(19) United States
(12) Patent Application Publication
(10) Pub. No.: US 2006/0253764 A1
(43) Pub. Date: Nov. 9, 2006

(54) Computer system and method for redundancy repair of memories installed in computer system

(75) Inventors: Sadao Kobayashi, Tokyo (JP); Seiichi Hannai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/407,054

(22) Filed: Apr. 20, 2006

(30) Foreign Application Priority Data
Apr. 22, 2005 (JP) 2005-125417

(51) Int. Cl. H03M 13/00

(52) U.S. Cl. 714/746

(57) ABSTRACT

A computer system is composed of a CPU, a memory module including a memory adapted to redundancy repair, a storage device separately provided from the memory device. When redundancy repair of the memory device is requested, a redundancy repair program is loaded into the storage device, and the CPU executes the redundancy repair program loaded into the storage device to implement redundancy repair of the memory device.

### BACKGROUND OF THE INVENTION

1. Field of the Invention

The present invention relates to a computer system and method, especially to a redundancy repair technique for memory devices installed on a memory module within a computer system.

2. Description of the Related Art

Large scale memories generally adopt redundancy repair architecture, because of the difficulty in complete elimination of manufacturing defects. Such memory devices incorporate a fuse circuit for storing fail addresses (that is, the addresses of the fail cells). When a fail cell is found within a memory device by a memory test, the fuse circuit is programmed to store the fail address. When an access to the fail cell is requested, the memory device provides an access to a redundant cell instead of the fail cell, to thereby achieve a successful data access.

Conventionally, the redundancy repair is achieved by laser trimming, which involves blowing fuses by laser beam radiation; however, the laser trimming suffers from a problem that the laser trimming can be implemented only on memory chips integrated on wafers; the laser trimming is not applicable to packaged memories.

One approach for achieving redundancy repair of packaged memories installed on a memory module is to incorporate electrically-programmable antifuses within the memories, which antifuses are programmed to store fail addresses, as disclosed in Japanese Laid-Open Patent Applications Nos. Jp-A-Heisei 6-295593, and Jp-A 2000-11864. In such a memory device, redundancy repair is performed as follows: Firstly, an electrical test is-implemented on a packaged memory to thereby obtain a fail log that describes fail addresses. This is followed by judging repairability of the memory device from the fail log. When the memory device is judged to be failed but repairable, the antifuses within the failed memory device are programmed by a memory tester to store the fail address(es).

Additionally, Japanese Laid-Open Patent Application No. Jp-A 2004-55100 discloses a technique for performing redundancy repair of DRAMs (dynamic random access memory) that are adapted only to redundancy repair by laser trimming after the DRAMs are installed on a memory module. This technique involves storing fail device information into a non-volatile memory installed on the memory module. When the computer system is started, the fail device information is transferred from the non-volatile memory to the DRAMs. When detecting that the destination of a requested access is a fail cell from the fail device information, the DRAM provides an access to a redundant cell instead of the fail cell.

The above-described techniques advantageously achieves redundancy repair after the installation of memories on a memory module; however, it would be further advantageous if a computer system is designed to perform redundancy repair of memories on a memory module after the memory module is installed in a computer system. Firstly, a computer system designed to perform redundancy repair of memories on a memory module therein advantageously eliminates the need for preparing an expensive memory tester adapted to the redundancy repair, effectively reducing the cost of the memories. Secondly, a computer system designed to perform redundancy repair of memories on a memory module therein allows end users to perform redundancy repair. This effectively reduces TAT (turn around time) and cost necessary for repairing memories that encounter a trouble during the end-user's use. Conventionally, repairing a memory that has failed during the end-user's use requires changing the failed memory or memory module with a new memory or memory module; however, this undesirably increases the TAT and cost for the repair. There is a need for providing a computer system adapted to perform redundancy repair of memories on a memory module incorporated therein.

### SUMMARY OF THE INVENTION

Therefore, an object of the present invention is to provide a computer system adapted to perform redundancy repair of memories on a memory module incorporated therein.

One issue in performing redundancy repair of a memory device on a memory module incorporated in a computer system is that the memory device to be repaired cannot be used as the main storage in performing the redundancy repair. Specifically, when a redundancy repair program is executed on a computer system to perform redundancy repair on a memory device, the redundancy repair program cannot be loaded into the memory device. Such problem is needed to be resolved in order to achieve redundancy repair of a memory device on a computer system.

The present invention avoids the above-described problem by using a storage device separately provided from memory devices that are used as the main storage in normal operations, and thereby achieves redundancy repair of the memory devices on a computer system. In a preferred embodiment, a cache memory within a CPU is used as the main storage, when the computer system performs the redundancy repair.

In an aspect of the present invention, a computer system is composed of a CPU, a memory module including a memory adapted to redundancy repair, a storage device separately provided from the memory device. When redundancy repair of the memory device is requested, a redundancy repair program is loaded into the storage device, and the CPU executes the redundancy repair program loaded into the storage device to implement redundancy repair of the memory device.

When the CPU includes a cache memory, the cache memory is preferably used as the storage device.

The computer system thus designed is especially suitable when the memory device is used as a main storage of the computer system in a normal operation.

In a preferred embodiment, the memory module further includes a non-volatile memory, and the CPU executes a test program to test the memory device. When the CPU find a fail address in the memory device, the CPU writes fail data indicative of the fail address into the non-volatile memory. The redundancy repair of the memory device is performed depending on the fail data.

The non-volatile memory is preferably used as a serial presence detect.

In another aspect of the present invention, a method addresses performing redundancy repair on a computer system including a CPU, a memory device used as a main storage of the computer system in a normal operation, and a storage device separately provided from the memory device. The method is composed of:

loading a redundancy repair program into the storage device;

executing the redundancy repair program loaded into the storage device, by the CPU to perform redundancy repair of the memory device.

### BRIEF DESCRIPTION OF THE DRAWINGS

FIG. 1 is a block diagram illustrating an exemplary structure of a computer system in accordance with the present invention; and

FIG. 2 is a flowchart illustrating an exemplary operation of the computer system shown in FIG. 1, in accordance with the present invention.

### DESCRIPTION OF THE PREFERRED EMBODIMENTS

Preferred embodiments of the present invention will be described below in detail with reference to the attached drawings.

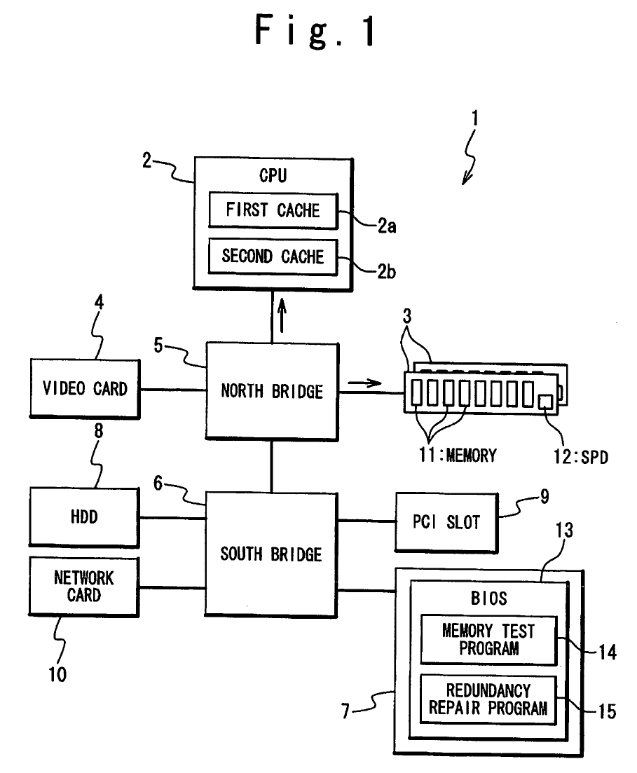

FIG. 1 is a block diagram illustrating an exemplary structure of a computer system 1 in one embodiment of the present invention. The computer system is composed of a CPU 2, memory modules 3, a video card 4, which are connected one another through a north bridge 5.

The CPU 2 includes a first cache 2a and a second cache 2b. The first cache 2a provides relatively high speed access, while having a reduced capacity. On the other hand, the second cache 2b provides relatively low speed access compared to the first cache 2a, while having an increased capacity. In one embodiment, the second cache 2b has a capacity of 2 Mbytes. The first cache 2a is an area to which the CPU 2 firstly tries to have an access, and the second cache 2b is an area to which the CPU 2 secondly tries to have an access when the first cache 2a do not contain desired data.

The memory modules 3 are each composed of a set of memory devices 11 and a SPD (serial presence detect) 12. The memory devices 11 are used as the main storage of the computer system 1 in normal operations. In this embodiment, DRAMs are used as the memory devices 11. The memory devices 11 are designed to be adapted to electrical redundancy repair. Specifically, the memory devices 11 incorporates antifuses therein, which are programmed to store fail addresses when redundancy repair is performed. When detecting an access to a fail cell from the fail addresses stored in the antifuses, the memory devices 11 provides an access to a redundancy cell instead of the fail cell.

The SPD 12 is a non-volatile memory device storing information related to the memory devices 11, including the types and capacities of the memory devices 11, the clock frequency, the signal timings, and the use or non-use of ECC (error check and correction) or parity check. In one embodiment, an EEPROM (electrically erasable programmable read only memory) is used as the SPD 12.

Connected to the north bridge 5 is a south bridge 6. The south bridge 6 is connected to a non-volatile memory 7 storing a BIOS (basic input/output system) 13, a hard disk drive 8, a PCI (peripheral component interconnect) slot 9, and a network card 10.

The BIOS 13 within the non-volatile memory 7 includes a memory test program 14 and a redundancy repair program 15. The memory test program 14 is a program used for test of the memory modules 3. When the computer system 1 is set to implement a test of the memory modules 3 in the booting procedure, the CPU 2 executes the memory test program 14 to perform a test of the memory modules 3. The redundancy repair program 16 is a program used for performing redundancy repair for the memory devices 11 on the memory modules 3. When the computer system 1 is set to implement redundancy repair of the memory devices 11, the CPU 2 executes the redundancy repair program 16.

One feature of the computer system 1 in this embodiment is that the computer system 1 is designed to implement on-board redundancy repair of the memory devices 11, which are used as the main storage of the computer system 1. Implementing redundancy repair of the memory devices 11 on the computer system 1 eliminates the need for using an expensive memory tester to repair the memory devices 11.

One issue in performing the redundancy repair of the memory devices 11 on the computer system 1 is that the memory devices 11 to be repaired are used as the main storage of the computer system 1. The computer system 1 requires a main storage when implementing desired operations, including the redundancy repair; however, the memory devices 11 cannot be used as the main storage of the computer system 1 in performing redundancy repair on the memory devices 11.

In order to avoid such problem, the computer system 1 in this embodiment uses a storage unit separately-provided from the memory devices 11, as the main storage, when performing the redundancy repair of the memory devices 11. More specifically, the computer system 1 uses the second cache 2b within the CPU 2 as the main storage when performing the redundancy repair of the memory devices 11. When the redundancy repair of the memory devices 11 is requested, the redundancy repair program 15 is loaded into the second cache 2a, and executed by the CPU 2. This achieves the redundancy repair of the memory devices 11.

A storage device dedicated for the redundancy repair of the memory devices 11 may be used in place of the second cache 2a. In this case, the redundancy repair program 15 loaded into the dedicated storage device. It should be noted, however, that the use of the cache memory within the CPU 2 as the main storage in performing the redundancy repair effectively reduces hardware of the computer system 1, and advantageously reduces the cost. An exemplary procedure of the redundancy repair of the memory devices 11 is described in detail in the following.

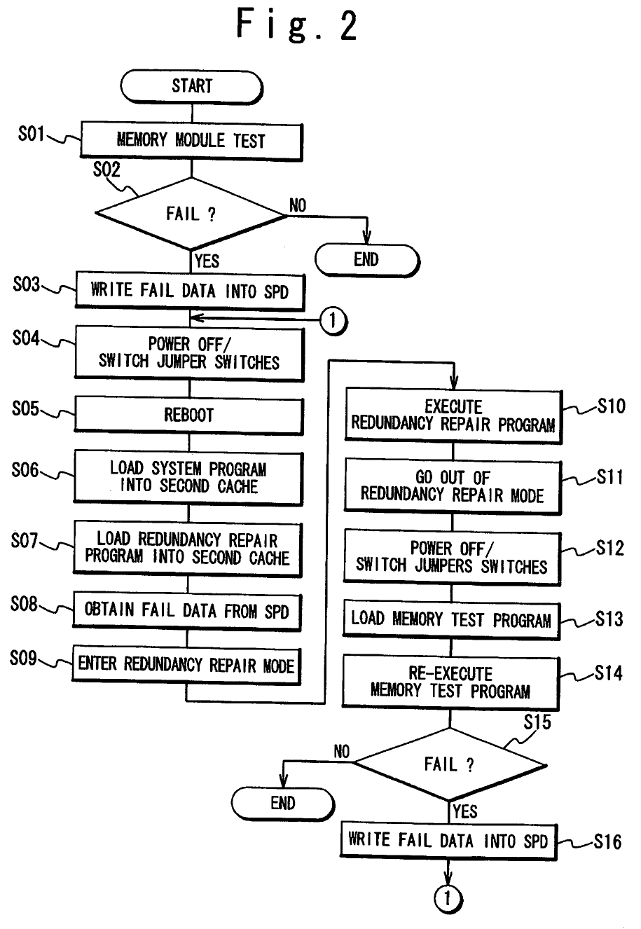

When the computer system 1 is booted, or a specific operation is conducted on the computer system 1, as shown in FIG. 2, the memory test program 14 within the BIOS 13 is executed to implement a test of the memory modules 3 at a step S01.

When no fail is found in the test of the memory modules 3, the procedure is normally terminated at a step S02. When any failure is found, fail data is written into the SPD 12 at a step S03. In one embodiment, the fail data may include module IDs identifying failed memory modules 3, memory IDs identifying failed memory devices 11, and data indicative of failed addresses. The computer system 1 displays an indication on a display screen (not shown), indicating that a failure(s) is found by the test of the memory modules 3.

When desiring to perform redundancy repair on the memory modules 11 on the memory modules 3, the user is requested to switch a jumper switch at a step S04 after shutting down the computer system 1. The jumper switch is used to instruct the computer system 1 to perform redundancy repair. A software switch may be used to instruct the computer system 1 to perform redundancy repair, in place of the jumper switch.

When the computer system 1 is rebooted at a step S05 after the jumper switch is switched, a system program is loaded into the second cache 2b within the CPU 2 at a step S06. In one embodiment, an input/output control module of the BIOS 13 is loaded into the second cache 2b from the non-volatile memory 7, and then a disk operating system (DOS) is loaded from the hard disk drive 8.

This is followed by loading the redundancy repair program 15 of the BIOS 13 into the second cache 2b of the CPU 2 at a step S07. As mentioned above, loading the redundancy repair program 15 into the second cache 2b is important for avoiding the problem that the memory devices 11 cannot be used as the main storage in performing the redundancy repair.

Additionally, the fail data is obtained from the SPD 12, and stored into the second cache 2b at a step S08. In this embodiment, the fact that the fail data is stored in the SPD 12 in a non-volatile manner is important, because the computer system 1 is rebooted before the redundancy repair is performed.

The memory device(s) 11 to be subjected to the redundancy repair is then placed into a redundancy repair mode at a step S09, while the remaining memory devices 11 are kept in a normal mode. The redundancy repair mode designates a mode in which the antifuses used to store fail addresses within the memory devices 11 are allowed to be programmed. Placing the memory devices 11 into the normal mode prohibits the antifuses within the memory devices 11 from being programmed. Preparing the memory devices 11 with the redundancy repair mode effectively avoids the antifuses within the memory devices 11 being accidentally programmed.

This is followed by executing the redundancy repair program 15 by the CPU 2 to perform the redundancy repair on targeted one(s) of the memory devices 11 at a step S10. Specifically, the antifuses within the targeted memory device(s) 11 are electrically blown and programmed to store the fail address(es) within the targeted memory device(s) 11.

After the redundancy repair is completed, the targeted memory device(s) 11 is switched out of the redundancy repair mode, and placed into the normal mode at a step S11.

The user is requested at a step S12 to shut down the computer system 1, and to then switch the jumper switch again. When the computer system 1 is rebooted after the jumper switch is switched, the memory test program 14 within the BIOS 13 is loaded into the second cache 2b at a step S13. The memory test program 14 is executed again to test the memory modules 3 at a step S14.

When no failure is founded by the test of the memory modules 3 at the step S14, the memory test program 14 is normally terminated at a step S15. When any failure is found, on the other hand, fail data is written into the SPD 12 at a step S16, in the same way as the step S03. The computer system 1 displays an indication on a display screen (not shown), indicating that a failure(s) is found by the test of the memory modules 3.

The set of the steps S04 to S16 are repeated to repair the memory devices 11 on the memory modules 3, till all the failures are removed from the memory modules 3.

In summary, the computer system 1 in this embodiment is designed to perform the on-board redundancy repair of the memory devices 11 on the memory modules 3, which are used as the main storage of the computer system 11. The problem that the memory devices 11 cannot be used as the main storage during the execution of the redundancy repair program 15 is resolved by using the second cache 2b within the CPU 2 as the main storage in performing the on-board redundancy repair.

It is apparent that the present invention is not limited to the above-described embodiments, which may be modified and changed without departing from the scope of the invention.

What is claimed is:

1. A computer system comprising:
a CPU;
a memory module including a memory device adapted to redundancy repair; and
a storage device separately provided from said memory device,
wherein a redundancy repair program is loaded into said storage device, when redundancy repair of said memory device is requested, and
wherein said CPU executes said redundancy repair program loaded into said storage device to implement redundancy repair of said memory device.

2. The computer system according to claim 1, wherein said storage device is a cache memory within said CPU.

3. The computer system according to claim 1, wherein said memory device is used as a main storage of said computer system in a normal operation.

4. The computer system according to claim 1, wherein said memory module further includes a non-volatile memory,
wherein said CPU executes a test program to test said memory device, and when said CPU find a fail address in said memory device, said CPU writes fail data indicative of said fail address into said non-volatile memory, and
wherein said redundancy repair of said memory device is performed depending on said fail data.

5. The computer system according to claim 4, wherein said non-volatile memory is used as a serial presence detect.

6. A method for performing redundancy repair on a computer system including a CPU, a memory device used as a main storage of said computer system in a normal operation, and a storage device separately provided from said memory device, said method comprising:
loading a redundancy repair program into said storage device;
executing said redundancy repair program loaded into said storage device, by said CPU to perform redundancy repair of said memory device.

7. The method according to claim 6, wherein said storage device is a cache memory within said CPU.
